(19) United States
(12) Patent Application Publication
(10) Pub. No.: US 2020/0314998 A1
(43) Pub. Date: Oct. 1, 2020

(54) IMPEDANCE CUSHION TO SUPPRESS POWER PLANE RESONANCE

(71) Applicant: Intel Corporation, Santa Clara, CA (US)

(72) Inventors: Khang Choong YONG, Puchong (MY); Ying Ern HO, Bayan Lepas (MY); Wil Choon SONG, Bayan Lepas FTZ (MY); Yun Rou LIM, Bayan Lepas (MY); Telesphor KAMGAING, Chandler, AZ (US)

(21) Appl. No.: 16/369,555

(22) Filed: Mar. 29, 2019

(51) Int. Cl. H05K 1/02; H05K 3/02; H05K 3/18; H05K 1/09

(52) U.S. Cl. CPC H05K 1/0224; H05K 3/027; H05K 3/188; H05K 2203/0723; H05K 2201/093; H05K 2201/0723; H05K 1/09

(57) ABSTRACT

Embodiments herein relate to systems, apparatuses, processes or techniques directed to an impedance cushion coupled with a power plane to provide voltage for a system, where the impedance cushion is dimensioned to suppress resonance of the power plane to mitigate RFI or EMI emanating from the power plane during operation.

### FIELD

Embodiments of the present disclosure generally relate to the field of package assemblies, and in particular package assemblies that include power planes.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Continued reduction in end product size of mobile electronic devices such as smart phones and ultrabooks is a driving force for the development of reduced size system in package components.

### BRIEF DESCRIPTION OF THE DRAWINGS

FIGS. 1A-1B illustrate an example cross-section of package assemblies with and without a power plane coupled with an impedance cushion, in accordance with embodiments.

FIGS. 2A-2L illustrate various examples of packages that include power planes coupled with one or more impedance cushions, in accordance with embodiments.

FIGS. 3A-3C illustrate examples of power plane resonances with and without impedance cushions, in accordance with embodiments.

FIG. 4 illustrates an example of the reduction of power plane to transmission line coupling when using impedance cushions, in accordance with embodiments.

FIGS. 5A-5B illustrate a top view of a power plane and a signal trace with and without impedance cushions, in accordance with embodiments.

FIGS. 6A-6L illustrate an example of a package assembly using an impedance cushion to suppress power plane resonance within the package at various stages of a manufacturing process, in accordance with embodiments.

FIG. 7 illustrates an example of a process to create a package having an impedance cushion to suppress power plane resonance, in accordance with embodiments.

FIG. 8 schematically illustrates a computing device, in accordance with embodiments.

### DETAILED DESCRIPTION

Embodiments of the present disclosure may generally relate to systems, apparatus, and/or processes directed to a power plane to provide voltage for a system and an impedance cushion coupled with the power plane, where the impedance cushion is dimensioned to suppress resonance of the power plane during operation to mitigate radio frequency interference (RFI) or electromagnetic interference (EMI) emanating from the power plane. In embodiments, one or more impedance cushions implemented as metal planes that are applied to or coupled with a power plane may be used to suppress RFI or EMI that may otherwise affect 4G or 5G components proximate to the power plane.

In legacy implementations, the resonance of metal power/ground/floating plane that limits the enabling of 4G/5G applications or circuitry within packages. In addition, the signal integrity issues may also be caused by the power plane to transmission line coupling that will be intensified by metal plane resonance. These resonance issues may limit the scaling of high-speed links such as USB3, PCIE Gen4, TBT, and memory.

For example, product miniaturization may cause 5G/Wi-Fi radio antennas to be placed closer to the printed circuit board (PCB). Noise will propagate from an exposed resonating power plane to the nearby radio antennas and will be stronger compared to the past. Coupling noise from a resonating power plane to the nearby radio antennas is inversely proportional to the square of the distance between them. With the constant drive towards mobile computing devices miniaturization, the 5G/WiFi ratio antenna has to be placed closer to the printed circuit board (PCB) within the system chassis, which significantly increases the noise coupling between the resonating power plane and the nearby ratio antenna causing EMC and RFI issues.

In addition, the power-ground dual referencing scheme for I/O routing has become unavoidable as PCB form factor shrinks in all x-y-z dimensions. Having perfect ground reference for all I/O routings while meeting cost effective PCB layer count, system X-YZ form factor requirements and power integrity (PI) design target may be extremely difficult. One of the concerns about power-ground dual referencing scheme is the coupling noise from the power reference plane to the signal traces, which then degrades signal integrity (SI) performance. A resonating power plane will intensify the impact of the coupling noise.

Legacy implementations have attempted to mitigate or suppress RFI or EMI using a number of techniques. For example, avoiding power plane routing at both top and bottom PCB layers that are exposed, limiting the size of the power plane if it has to be routed at the top/bottom PCB layers, adding EMC and RFI resistor-capacitor (RC) filtering by placing resistors and capacitors on the PCB, adding physical onboard shielding, placing radio antennas further away from the system PCB, or implementing a full ground referencing scheme instead of dual referencing scheme for input output (I/O) routings where signals reference to a mixture of ground and power planes.

These legacy implementations may have disadvantages, including requiring additional PCB layer counts resulting in higher cost, limiting power integrity (PI) design optimization which may involve system performance trade-offs. Avoiding or limiting power plane routing on top and bottom PCB layers reduces PCB physical design flexibility, limits PI design optimization, and limits system performance. Adding RC filter on board adds cost, limits PCB real estate, and increases design complexity. Adding physical on board shield adds cost and limits Z-height for thin systems. Increasing the distance between antennas and the PCB limits system form factor miniaturization, and full ground referencing schemes require additional PCB layers, which also adds cost and limits Z-height for thin systems.

Some embodiments described herein minimize the magnitude of the reflection of the power plane by elevating the metal thickness of the power plane to form the impedance-cushion around the metal plane peripheral. Particularly at the region with abrupt impedance change, such as at the boundary between air and metal planes of the impedance cushion-enhanced power plane.

In embodiments, the impedance-cushion is able to provide gradual impedance change which helps to dampen the magnitude of the reflection at the impedance discontinuity boundaries, for example at the boundary of a 2 Ω-plane and the 377 Ω-air, with a reflection coefficient of ˜+0.98. The impedance cushion is able to effectively help to spread the intensity of the electromagnetic (EM) wave built up at the resonance frequencies. The impedance cushions formed by increasing the thickness of the metal power plane at various locations could be formed either by additional metal deposition on the metal plane peripheral, or utilizing an adjacent signal metal layer, for example in a dielectric, and connect them to the metal plane using plated through holes (PTH) or vias.

Implementations of embodiments described herein, as compared to legacy approaches, may result in lower EMI/EMC/RFI risk as the electric field on the resonating power plane will be reduced. Better SI performance will be seen due to lower noise coupling from power plane to nearby signal routing. In addition, embodiments described herein may not require additional cost and may not impact the PCB stackup, or Z-height. A metal power plane with impedance-cushion built around the boundary of the power plane could help to suppress the resonance intensity by >50% to alleviate the EMI/RFI risk and to promote electromagnetic compatibility (EMC). In addition, by reducing the resonance intensity by >50%, the power-plane to transmission line coupling could also be reduced by >50% to reduce signal to power noise ratio, which improves signal quality.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

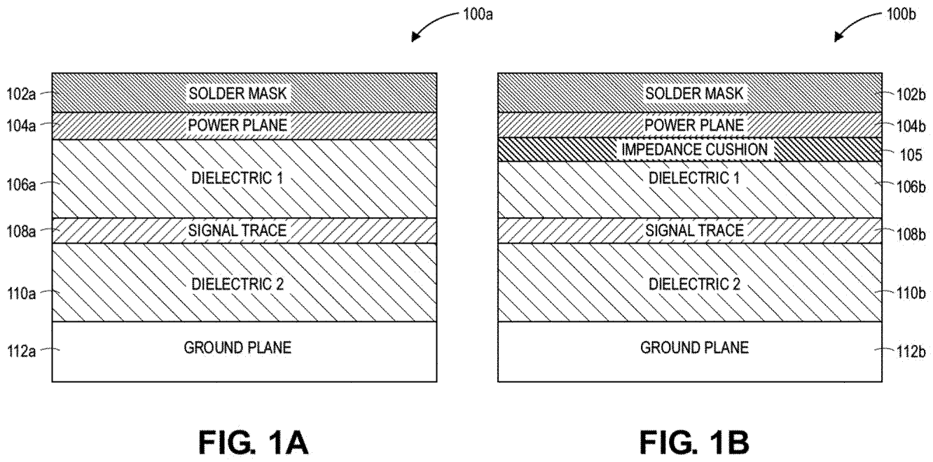

FIGS. 1A-1B illustrate an example cross-section of package assemblies with and without a power plane coupled with an impedance cushion, in accordance with embodiments. FIG. 1A shows package 100a that includes a solder mask layer 102a, a power plane 104a, a first dielectric layer 106a, a signal trace 108a, a second dielectric layer 110a, and the ground plane 112a. FIG. 1B shows package 100b that includes a solder mask layer 102b, and a power plane 104b, which may be similar to solder mask layer 102a and power plane 104a of FIG. 1A.

However, package 100b includes an impedance cushion layer 105 that is coupled to the power plane 104b and extends into the first dielectric layer 106b. In embodiments, the impedance cushion layer 105 may include one or more metal plates that are attached to the power plane 104b that cause the height of the power plane 104b to extend into the first dielectric layer 106b. In embodiments, metal plates or other impedance cushion features may not extend all the way into the impedance cushion layer 105. In embodiments, the thickness of the first dielectric layer 106a of package 100a may be a same height as a combination of the impedance cushion layer 105 together with the first dielectric layer 106b. In this way, the overall height of package 100a without the impedance cushions may be the same height as the package 100b with impedance cushions.

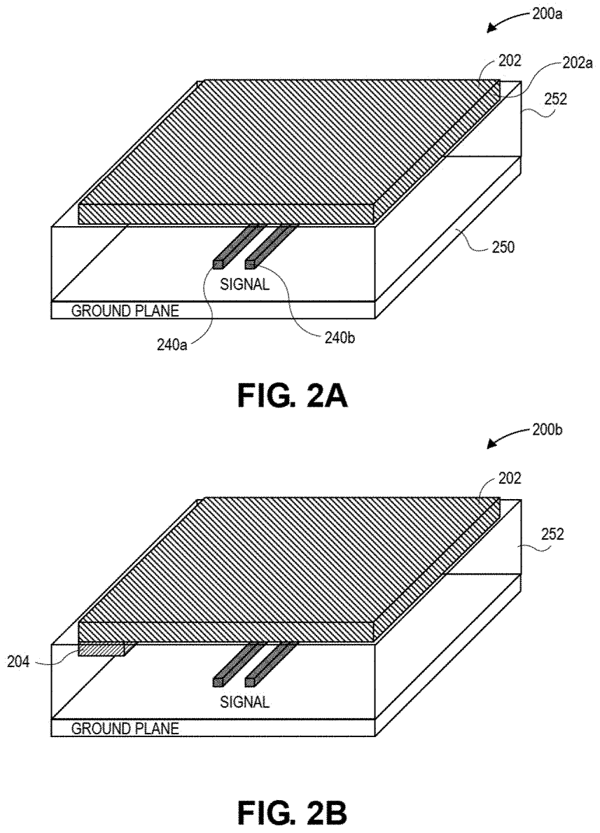

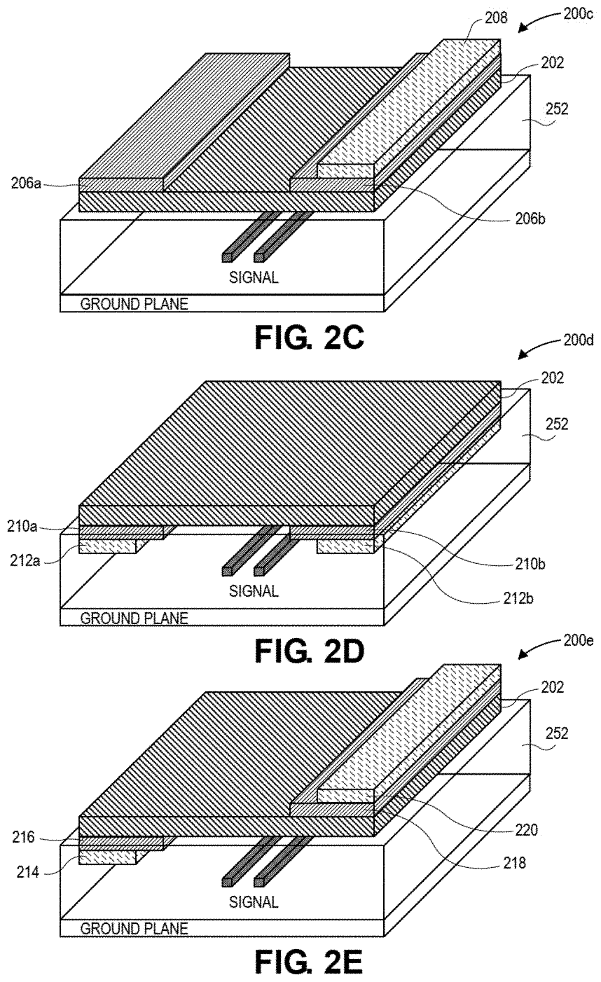

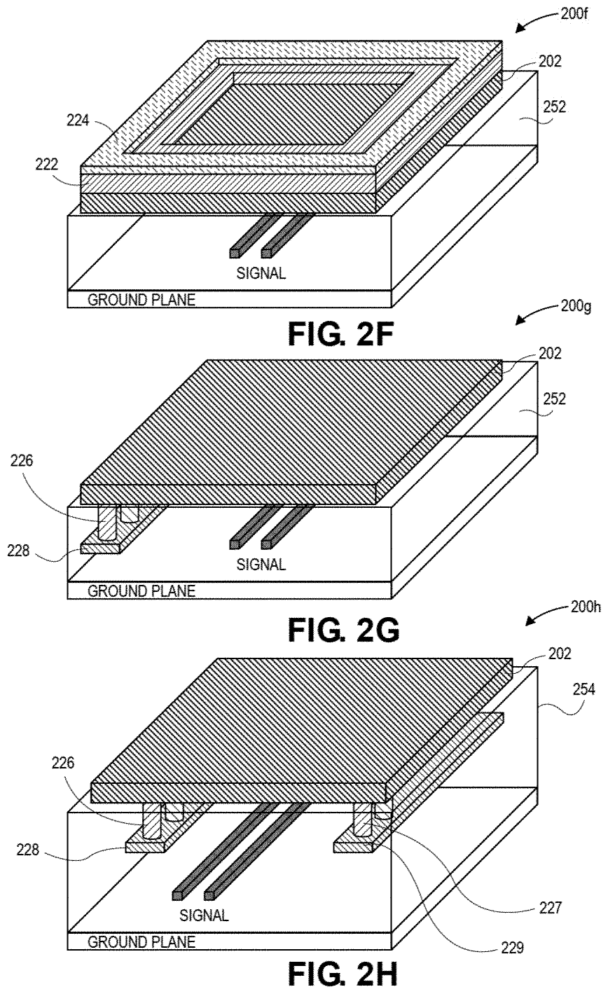

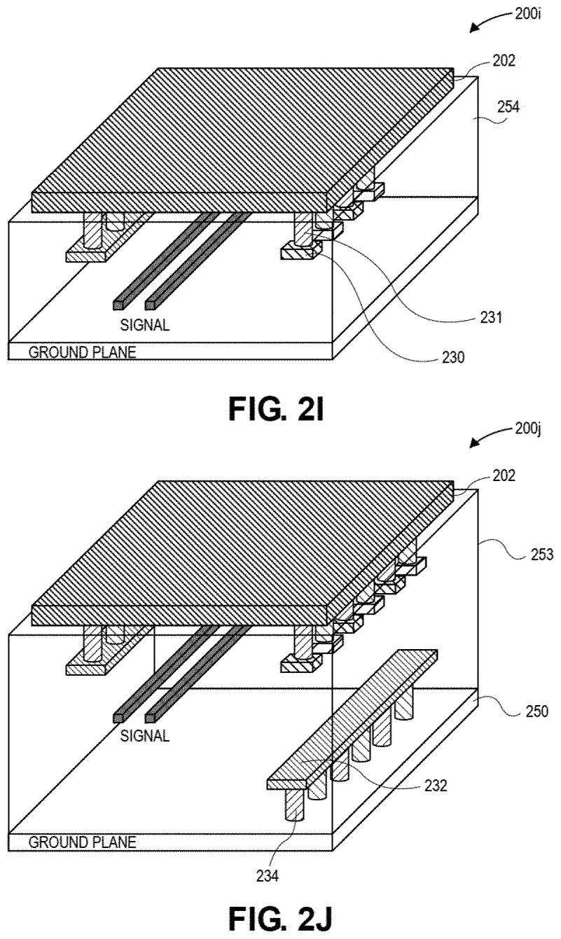

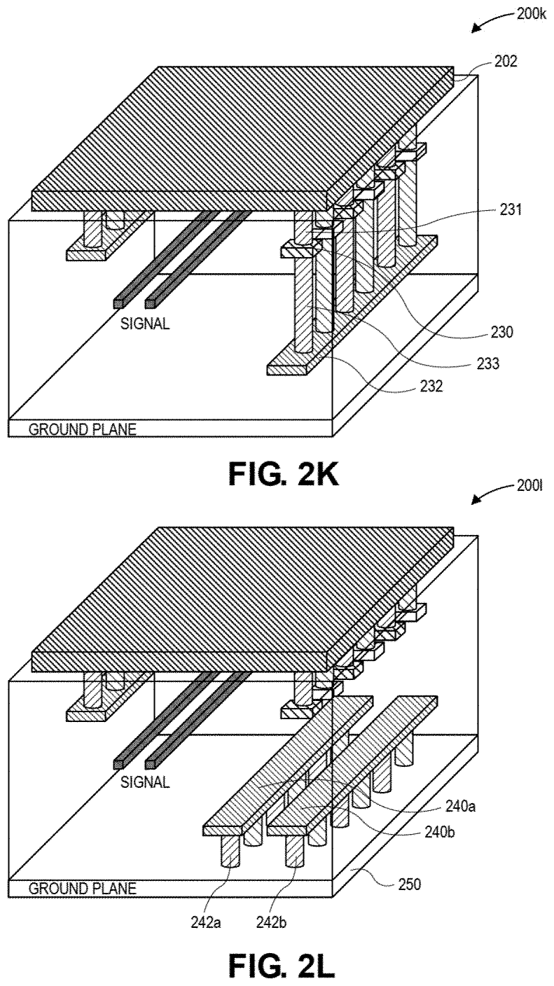

FIGS. 2A-2L illustrate various examples of packages that include power planes coupled with one or more impedance cushions, in accordance with embodiments. FIG. 2A shows package 200a that includes a power plane 202 that is coupled to one side of a dielectric 252. The other side of the dielectric is coupled with a ground plane 250. Within the dielectric 252, and between power plane 202 and ground plane 250 are two signal lines 240a, 240b.

During operation, the power plane 202 may reflect EMI/RFI, particularly at the edges 202a of the power plane 202 that meet the ambient air. For example, the EMI/RFI may affect signals carried along the signal lines 240a, 204b and affect the integrity of the operation and/or cause the system to fail to meet its operational parameters. In addition, the package 200a may be near 4G/5G components (not shown) or EMI/RFI from the power plane 202 may affect the proper operation of the 4G/5G components.

FIG. 2B shows a package 200b, which may be similar to package 200a, that has a power plane 202 that includes an impedance cushion 204 extension into the dielectric 252. In embodiments, the impedance cushion 204 may be formed with the same type of metal or a different type of metal used in the power plane 202. In embodiments, the power plane 202 and the impedance cushion 204 may be formed as a unitary whole.

As shown in diagram 200b, one or more edge surfaces of the impedance cushion 204 may align with one or more edge surfaces of the power plane 202, such that an edge of the impedance cushion 204 and an edge of the power plane 202 form a plane. By effectively increasing the metal thickness of the power plane 202 by adding impedance cushion 204, the magnitude of an EMI/RFI reflection created by the power plane 202 may be reduced. This may be accomplished by providing a gradual impedance change to dampen the magnitude of the reflection at any impedance discontinuity at the edge of the power plane 202, which is a boundary between the electrical resistance of the power plane 202 and the electrical resistance of surrounding air.

The resonance suppression properties of the impedance cushion 204 may be adjusted by altering the thickness, the length, the breadth, or the composition of the impedance cushion 204 with respect to the power plane 202. In embodiments, the impedance cushion 204 may have a uniform thickness and shape, such as a rectangular prism, or it may have a varied thickness and/or irregular shape.

FIG. 2C shows diagram 200c that includes a power plane 202 coupled with a plurality of impedance cushions 206a, 206b, 208. In embodiments, the impedance cushions may be above the dielectric layer 252 at a particular plane with respect to power plane 202, such as impedance cushions 206a, 206b. In embodiments, additional impedance cushions 208 may be stacked on other impedance cushions 206b. The dimensions, composition, and positioning of each of the impedance cushions 206a, 206b, 208 may be selected with respect to desired resonance characteristics of the power plane 202 when in operation. In embodiments, the impedance cushions 206a, 206b, 208 may be unitary with the power plane 202.

FIG. 2D shows diagram 200d, which may be similar to diagram 200c, shows a plurality of impedance cushions 210a, 210b, 212a, 212b coupled with a power plane 202 and that are within a dielectric layer 252. The impedance cushions 210a, 212a and 210b, 212b are stacked as shown, and the location of the respective stacking changes the impedance of the power plane 202 at that location. In embodiments, the impedance cushions 210a, 210b, 212a, 212b may be unitary with the power plane 202.

FIG. 2E shows diagram 200e that includes a power plane 202 coupled with a plurality of impedance cushions. In particular, impedance cushions 214, 216 may be coupled on a first side of the power plane 202 extending into a dielectric layer 252, and impedance cushions 218, 220 may be coupled to a second side of the power plane 202 opposite the first side.

FIG. 2F shows diagram 200f that includes two impedance cushion layers 222, 224 that are coupled with the power plane 202. As shown, the impedance cushion layers 222, 224 extend to the edges of the power plane 202 with different offset distances. As shown, the impedance cushions 222, 224 are above a dielectric layer 252, however in other embodiments, they may be within the dielectric layer 252. In embodiments, the impedance cushions 222, 224 may be unitary with the power plane 202.

FIG. 2G shows diagram 200g that includes an impedance cushion 228 that is coupled with the power plane 202 by connectors 226. In embodiments, these connectors may be copper pillars, or some other electrically conductive material to electrically and physically couple the power plane 202 with the impedance cushion 228 to modify the resonance characteristics of the power plane 202. The impedance cushion 228 and the connectors 226 may be within a dielectric layer 252. In embodiments, the distance between the power plane 202 and the impedance cushion 228 may be varied based upon desired resonance suppression characteristics.

FIG. 2H shows diagram 200h, which is similar to diagram 200g, but includes a second impedance cushion 229 that is coupled with the power plane 202 by connectors 227. In embodiments, the second impedance cushion 229 may be a same distance or a different distance from the power plane 202 as impedance cushion 228. In embodiments, impedance cushions 228, 229 may be generally parallel to each other, or may be skewed.

FIG. 2I shows diagram 200i, which may be similar to diagram 200h, where instead of one impedance cushion 229 of diagram 200h, there are multiple impedance cushions 230 that are individually connected to the power plane 202 by connectors 231. In embodiments, these impedance cushions 230 may be of similar shape and orientation. In other embodiments, these impedance cushions 230 may be of different thicknesses, shapes, orientations, or metals to tune the resonance suppression characteristics of the power plane 202.

FIG. 2J shows diagram 200j, which may be similar to diagram 200i, but also includes another impedance cushion structure 232 that is electrically and physically coupled to the ground plane 250 using connectors 234. In embodiments, the impedance cushion structure 232 may have a similar function and/or suppression characteristics as impedance structure 204 of FIG. 2B.

FIG. 2K shows diagram 200k, which may be similar to diagram 200j, but includes a second connector 233 to physically and electrically couple, respectively, the impedance cushions 230 with the additional impedance cushion 232. In embodiments, the second connector 233 may be made of the same material or different material as connector 231. In embodiments, not all impedance cushions 230 may include a second connector 233 to couple to the additional impedance cushion 232. In embodiments, the impedance cushion structure 232 may have a similar function and/or suppression characteristics as impedance structure 204 of FIG. 2B.

FIG. 2L includes diagram 200l, which may be similar to diagram 200j, where there are two impedance cushions 240a, 240b that are respectively coupled to the ground plane 250 by connectors 242a, 242b. In embodiments, the impedance cushions 240a, 240b may have a similar function and/or suppression characteristics as impedance structure 204 of FIG. 2B.

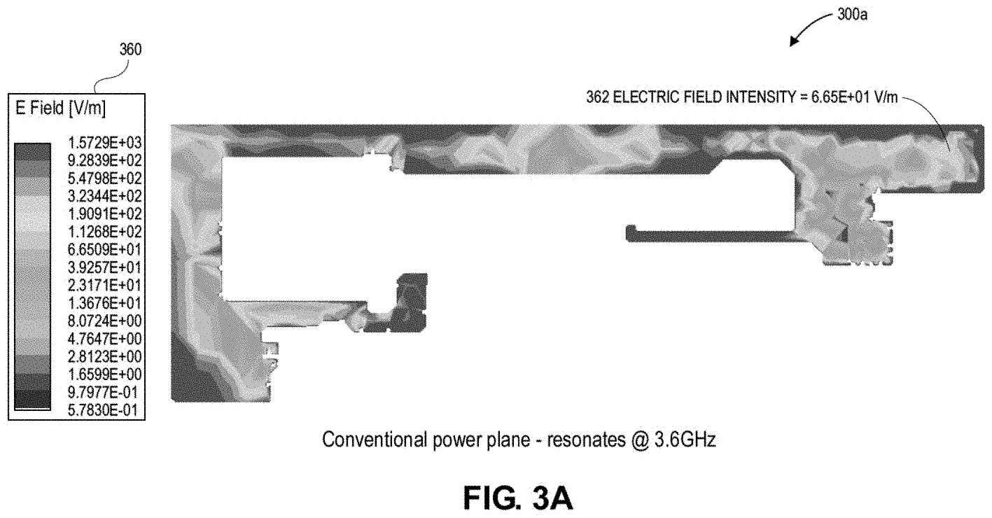

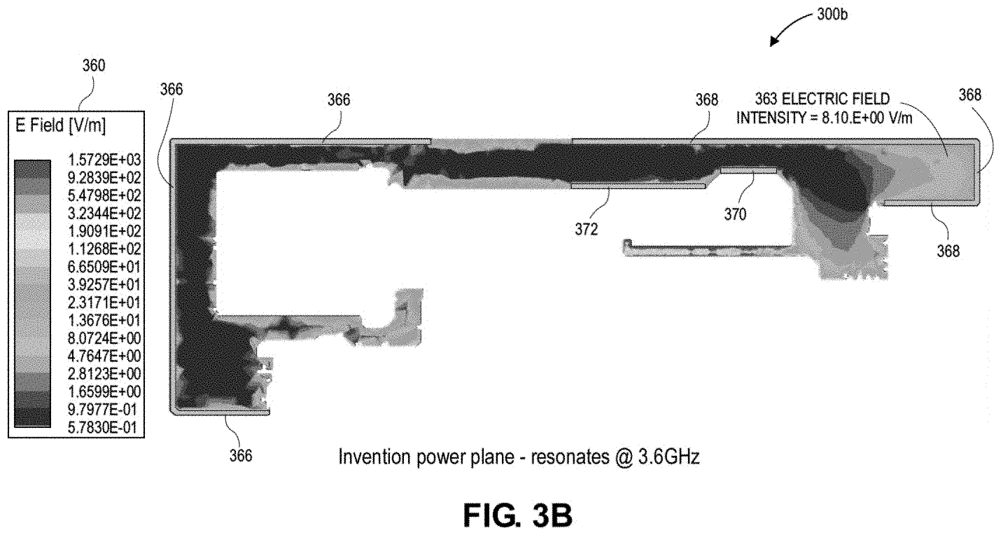

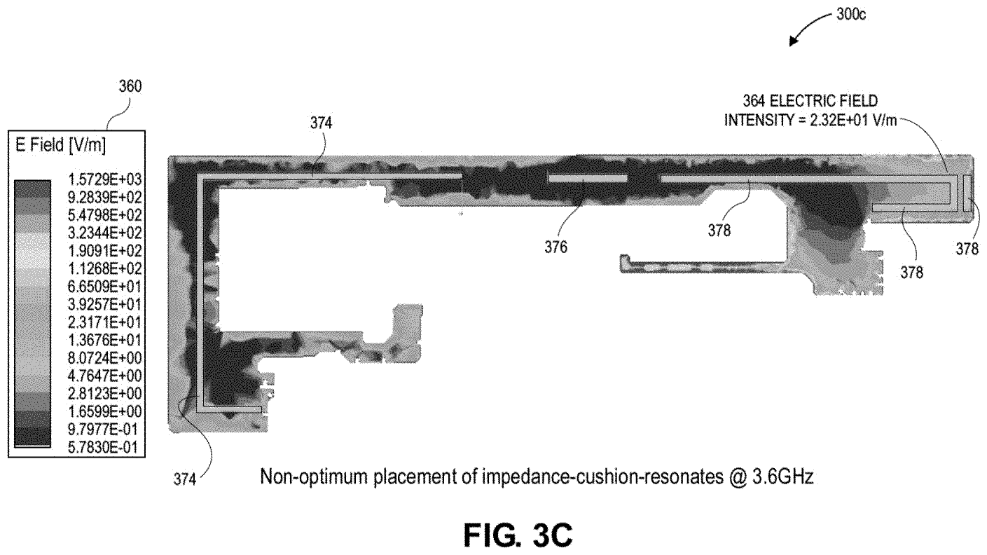

FIGS. 3A-3C illustrate examples of power plane resonances with and without impedance cushions, in accordance with embodiments. Diagrams 300a-300c depict a top view of various aspects of electric field intensity of various implementations of a power plane at a resonance frequency of 3.6 GHz. FIG. 3A shows diagram 300a that shows an electric field intensity map for a legacy power plane implementation, such as shown by a cross section view in FIG. 1A.

The various shadings in diagram 300a show varying levels of electric field intensity for the legacy power plane implementation, which may be mapped to the electric field key 360. As shown, at location 362, the electric field intensity is 6.65E+01 V/m.

FIGS. 3B-3C include diagrams 300b, 300c that show an electric field intensity map that implements an embodiment of the techniques described herein, in non-limiting examples as shown in a cross section view in FIG. 1B, and in perspective illustrative views of FIGS. 2B-2L. Diagram 300b shows an example of an optimal placement of impedance cushions 366, 368, 370, 372 on the surface of the power plane and at an edge. As shown, at location 363, which is at the same location as location 362 in diagram 300a, the electric field intensity has dropped to 8.1E+00 V/m, a greater than 70% improvement as compared to diagram 300a.

Diagram 300c shows an example of a non-optimal placement of impedance cushions 374, 376, 378 within the power plane but not at an edge of the power plane. As a result of this non-optimal placement, at location 364, which is at the same location as location 363 in diagram 300b, there is an increase in electric field intensity to 2.32E+01 V/m.

Diagram 300b show the power plane edge is an optimal location, while moving the impedance cushion from the edge to the middle causes non-optimal results. In embodiments, the optimal location of impedance cushion placement is at a region with abrupt impedance discontinuities, which is typically at the edge of a metal power plane. Placing an impedance cushion at that location provides gradual impedance change that helps to dampen and/or spread the intensity of the electromagnetic (EM) wave built up via multi-reflection caused by impedance discontinuities.

FIG. 4 illustrates an example of the reduction of power plane to transmission line coupling when using impedance cushions, in accordance with embodiments. Diagram 400 shows test results of the comparison between a legacy power plane implementation, for example as shown in FIGS. 1A and 2A, and a power plane implementation using an embodiment described herein, for example FIGS. 1B and 2B-2L. The graph plots the legacy results 482 on top of the impedance cushion results 484. At 3.6 GHz, there is a 5.5 dB difference 486 in power plane to signal trace, such as signal trace is 240a, 240b of FIG. 1A, coupling.

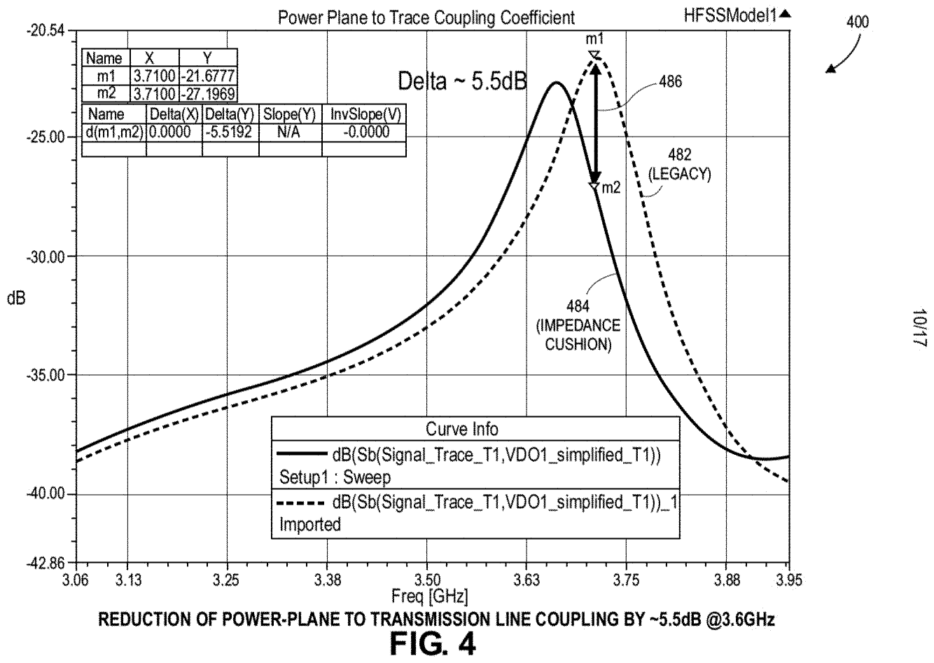

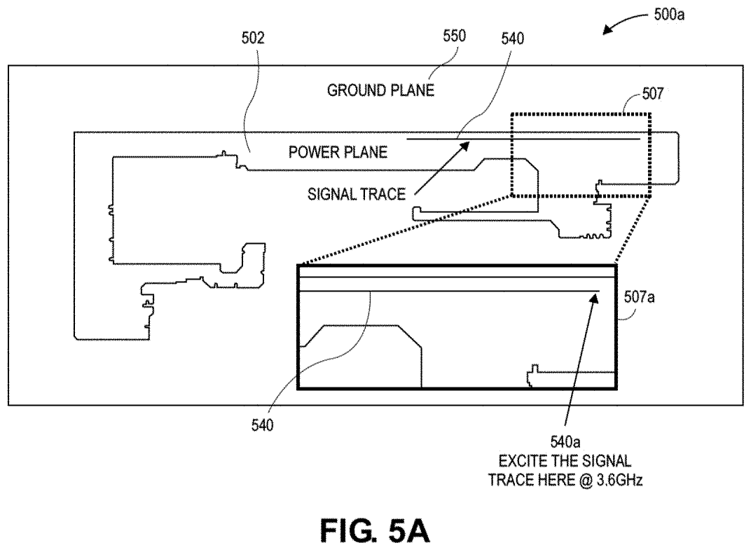

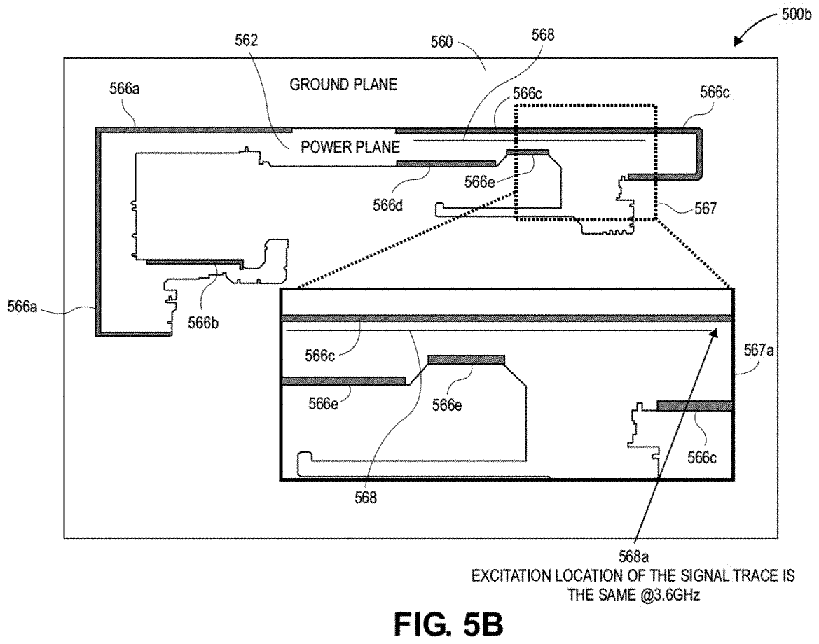

FIGS. 5A-5B illustrates a top view of a power plane and a signal trace with and without impedance cushions, in accordance with embodiments. In embodiments, FIGS. 5A-5B demonstrate the set up to test embodiments using high-frequency structure simulator (HFSS) simulation, the results of which may be shown with respect to diagrams 300a, 300b, 300c respectively of FIGS. 3A, 3B, 3C, and diagram 400 of FIG. 4. With respect to FIG. 5A, diagram 500a shows a schematic of a package with a ground plane 550, a power plane 502, and a signal trace 540. In embodiments, diagram 500a is a simulation setup used to obtain the results shown in illustration 300a of FIG. 3A. The area 507 is shown in greater detail in schematic 507a, that shows the end 540a of the signal trace 540 that was excited at 3.6 GHz, as part of test associated with FIG. 3A and FIG. 4.

With respect to FIG. 5B, diagram 500b shows a schematic of a package with a ground plane 560, a power plane 562, a signal trace 568, and impedance cushions 566a-566e. In embodiments, diagram 500a is a simulation setup used to obtain the results shown in illustration 300b of FIG. 3B related to optimal impedance cushion placement. The area 567 is shown in greater detail in schematic 567a, that shows the location 568 of the excitation of the signal trace at 3.6 GHz.

As shown, FIGS. 5A, 5B show top views, FIGS. 1A, 1B show side views, of both a legacy power plane implementation and a power plane embodiment, respectively, described herein. One single ended signal trace 540, 568 is placed in between these two metal planes. The smaller top metal plane is assigned as power plane 502, 562, while bottom metal plane is assigned as a ground plane 550, 560.

A difference between this embodiment implementation compared to the legacy implementation is that: protruded metal impedance cushion structure 566a-566e (0.3 mm width; 0.013 mm height) is added at the bottom and along the edge of resonating power plane. Note that the dielectric thickness in between power plane 502, 562 and signal trace 540, 568 remained unchanged. The impedance cushion structure 566a-566e is added at the power plane 562 edge because the intensity of electric field is at its highest at the power plane 562 edge during resonance, thus such placement maximizes the effectiveness of power plane resonance noise suppression during operation. Adding an impedance cushion structure elsewhere may not be as effective because the field intensity at a non-edge area is relatively lower. Although placing an impedance cushion at this area does suppress some resonance noise, it does not contribute much improvement to overall noise suppression.

For FIGS. 5A, 5B, the signal traces are excited at 3.6 GHz (resonance frequency of the power plane), and power plane electric field intensity is observed, as shown with respect to FIGS. 3A-3C. High resonating power plane electric field indicates that a greater noise level will be radiated from the power plane to nearby signals and radio antennas and cause interference which may result in device reliability issues.

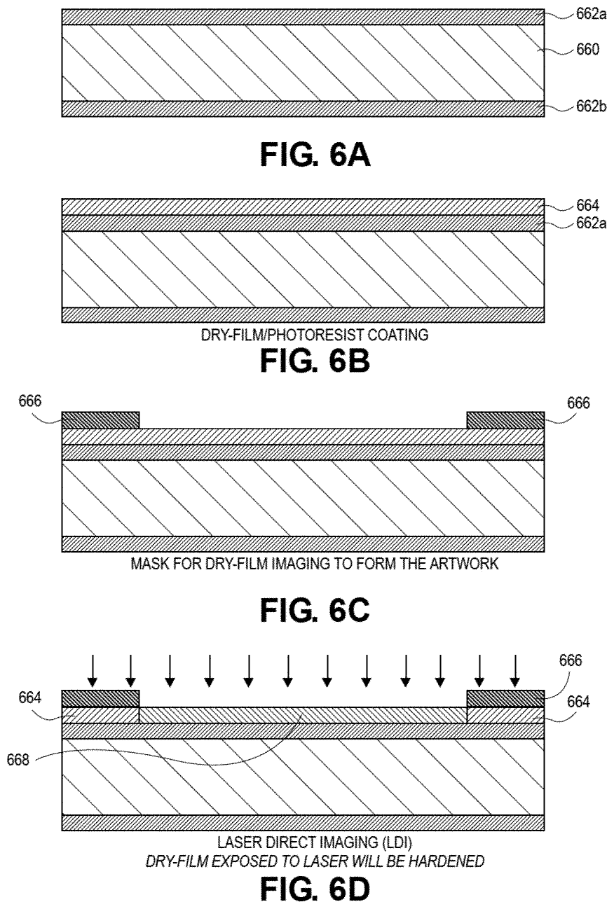

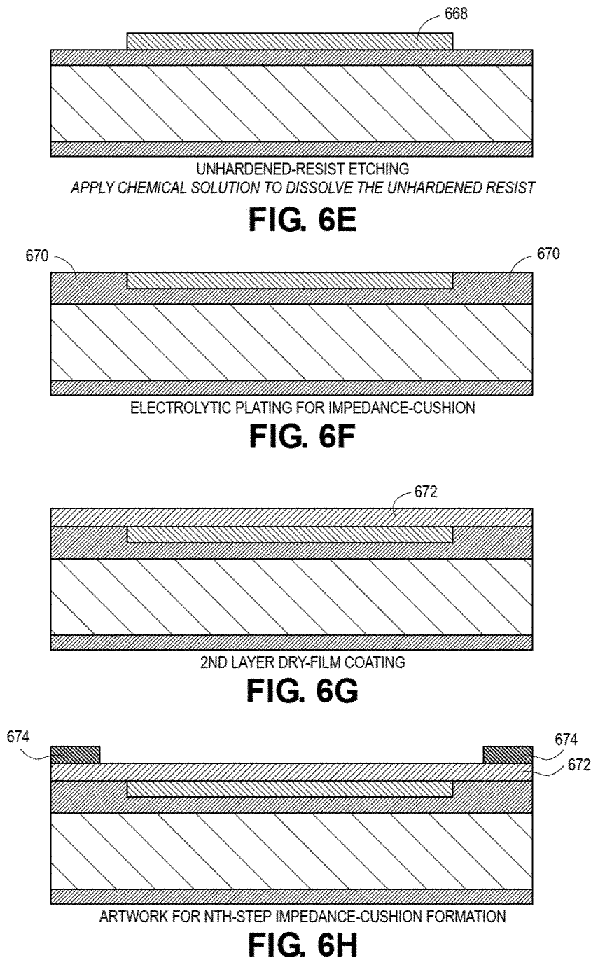

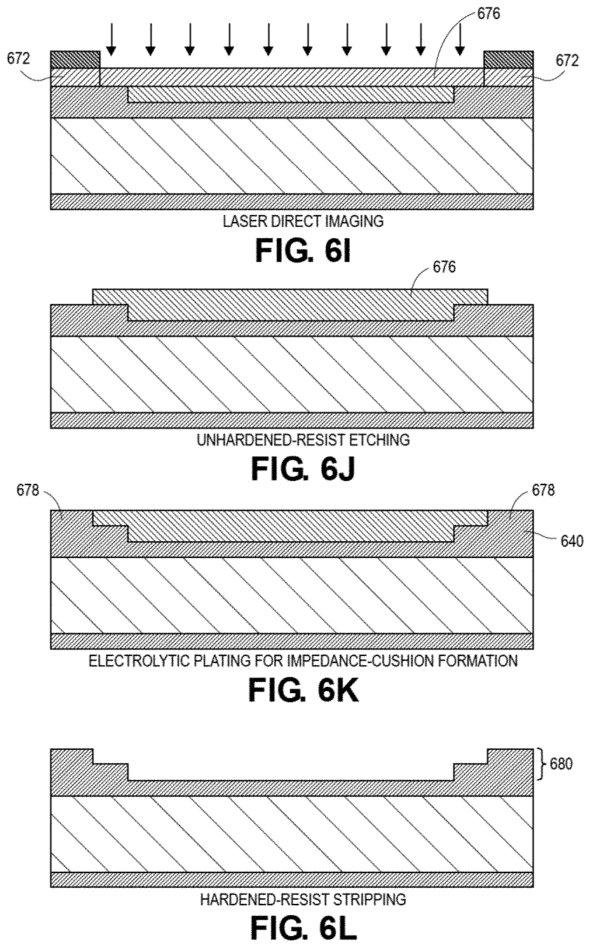

FIGS. 6A-6L illustrate an example of a package assembly using an impedance cushion to suppress power plane resonance within the package at various stages of a manufacturing process, in accordance with embodiments. At FIG. 6A, the package may include a prepeg material 660 that with copper foil 662a, 662b, on either side of the prepeg material 660. In embodiments, the prepeg material may be a combination of fiberglass and resin, or may be of some other material, in particular a dielectric material. In embodiments, the copper foil 662a, 662b may be some other metal or alloy that may be used as a power plane, for example power plane 104b of FIG. 1B. In embodiments, the top copper foil 662a may be used as all or part of a power plane, and the bottom copper foil 662b may be used as all or part of a ground plane.

FIG. 6B illustrates a dry film and/or photoresist coating 664 applied to the top copper foil 662a.

FIG. 6C illustrates a photo mask 666 applied to the photoresist coating 664 in preparation for imaging to form at least a portion of the artwork to create an impedance cushion.

FIG. 6D illustrates the result of laser direct imaging (LDI) applied to the package. After LDI, the photoresist 668 exposed to the laser will be hardened, while the portions of the photoresist 664 that are blocked by the photo mask 666 will not be hardened or un-hardened.

FIG. 6E illustrates the result of an etching of the un-hardened resist layer 664, to leave the hardened resist layer 668. In embodiments, this etching may include applying a chemical solution to dissolve the unhardened resist layer 664.

FIG. 6F illustrates an application of electrolytic plating 670 to the package. In embodiments, the electrolytic plating 670, which may copper or some other metal, may replace the volume that the unhardened photoresist 664 occupied in FIG. 6D. The electrolytic plating 670 will form a portion of the impedance cushion.

FIG. 6G illustrates an application of a second layer of photoresist coating 672, which may be similar to the photoresist coating 664 of FIG. 6B, applied to the package. In embodiments, the second layer of photoresist coating 672 may be a dry-film coating.

FIG. 6H illustrates an application of a photo mask 674, which may be similar to photo mask 666 of FIG. 6C, on the photoresist coating 672. The photo mask 674 is used to define a second layer of an impedance cushion on the package.

FIG. 6I illustrates the result of LDI applied to the package. After LDI, the photoresist exposed to the LDI will be hardened, leaving hardened photoresist 676.

FIG. 6J illustrates the result of the removal of the photo mask 674 and the etching of the unhardened photoresist 672.

FIG. 6K illustrates the application of electrolytic plating 678 on the metal layer 640 to makeup a second layer of the impedance cushion. In embodiments, the electrolytic plating 678 is copper or some other metal.

Note that the steps shown in FIG. 6G through FIG. 6K may be repeated multiple times to create additional layers of the impedance cushion. Also, varying the placement and thickness of the photo mask 674, which will adjust the placement and thickness of the electrolytic plating 678, and each repeated step will result in a different shape of the impedance cushion and its resulting resonance dampening performance on the power plate, such as copper layer 662b of FIG. 6A.

FIG. 6L illustrates a final step in the creation of an impedance cushion 680 by stripping the hardened resist layers 676, 668 from the package.

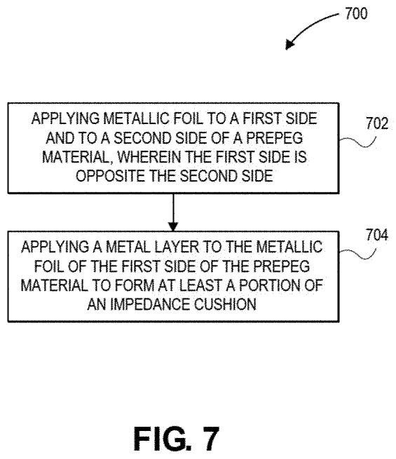

FIG. 7 illustrates an example of a process to create a package having an impedance cushion to suppress power plane resonance, in accordance with embodiments. Process 700 may be performed by one or more elements, techniques, or systems that may be described herein at least with respect to FIGS. 1A-6L.

At block 702, the process may include applying metallic foil to a first side and to a second side of a prepeg material, wherein the first side is opposite the second side. In embodiments, the prepeg material may be similar prepeg material 660 of FIG. 6A. The prepeg material may be a combination of fiberglass and resin, or maybe of some other material, in particular a dielectric material. In embodiments, the metallic foil may be a copper foil similar to the copper foil 662a, 662b of FIG. 6A. In embodiments, the copper foil may be some other metal or alloy that may be used as a power plane or a portion thereof, or as a ground plane or a portion thereof. In embodiments, the copper foil may be applied as a foil layer, or may be deposited as part of a sputtering process.

At block 704, the process may include applying a metal layer to the metallic foil of the first side of the prepeg material to form at least a portion of an impedance cushion. In embodiments, the metal layer may correspond at least to metal layer 105 of FIG. 1B, 206a, 206b, 208 of FIG. 2C, 218, 220 of FIG. 2E, 222, 224 of FIG. 2F, 670 of FIG. 6F, or 678 of FIG. 6K. In embodiments, the metal layer may be copper or some other metal or metallic alloy. In embodiments, the dimension, thickness, geometry, and/or orientation of the metal layer may be dimensioned based upon resonance suppression characteristics when the metal layer is attached to a power plane, which may include the metallic foil of the first side of the prepeg material as described above.

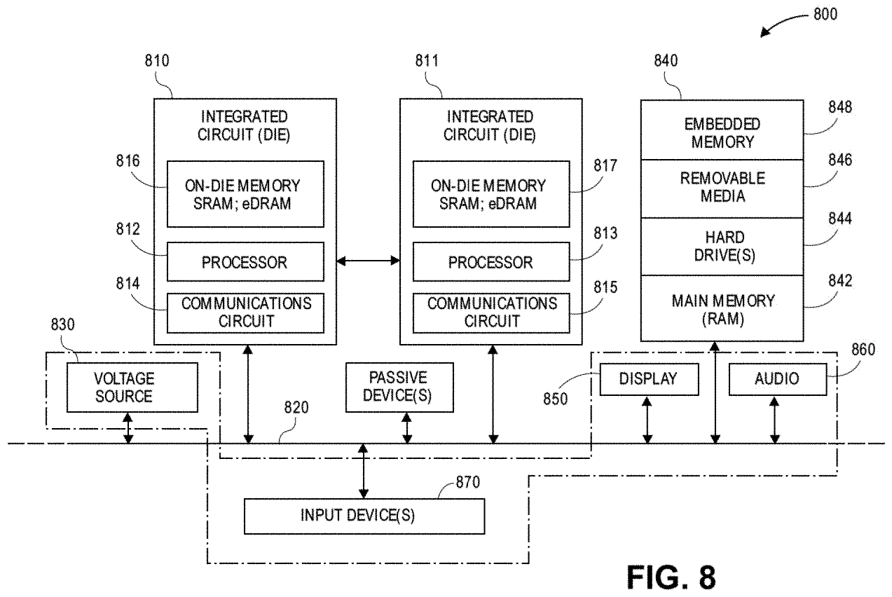

FIG. 8 schematically illustrates a computing device, in accordance with embodiments. The computer system 800 (also referred to as the electronic system 800) as depicted can embody an impedance cushion to suppress power plane resonance, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, an impedance cushion to suppress power plane resonance, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having an impedance cushion to suppress power plane resonance, according to any of the several disclosed embodiments and their equivalents, an electronic system, a computer system, one or more methods of fabricating an integrated circuit, and one or more methods of fabricating an electronic assembly that includes a package substrate having an impedance cushion to suppress power plane resonance, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having an impedance cushion to suppress power plane resonance embodiments and their equivalents. A foundation substrate may be included, as represented by the dashed line of FIG. 8. Passive devices may also be included, as is also depicted in FIG. 8.

### Examples

The following paragraphs describe examples of various embodiments.

Example 1 is an apparatus, comprising: a power plane to provide voltage for a system; and an impedance cushion coupled with the power plane, wherein the impedance cushion is dimensioned to suppress resonance of the power plane during operation to mitigate radio frequency interference (RFI) or electromagnetic interference (EMI) emanating from the power plane.

Example 2 may include the apparatus of example 1, wherein the impedance cushion is directly coupled with the power plane; and wherein a side of the impedance cushion and a side of the power plane form a plane.

Example 3 may include the apparatus of example 1, wherein the impedance cushion and the power plane are made of metal materials.

Example 4 may include the apparatus of example 3, wherein the impedance cushion and the power plane are made of different metal materials or have different electrical conductivity properties.

Example 5 may include the apparatus of example 1, wherein the power plane has a first side and a second side opposite the first side; wherein the impedance cushion is coupled to the second side of the power plane; and wherein the second side of the power plane and the impedance cushion are to couple with a dielectric material.

Example 6 may include the apparatus of example 1, wherein the impedance cushion has a uniform thickness.

Example 7 may include the apparatus of example 1, wherein the impedance cushion is a first impedance cushion with a first thickness value; and further comprising a second impedance cushion with a second thickness value directly coupled with the power plane or with the first impedance cushion.

Example 8 may include the apparatus of example 7, wherein the first thickness value and the second thickness value are different values.

Example 9 may include the apparatus of example 7, wherein a side of the second impedance cushion and a side of the power plane form a plane.

Example 10 may include the apparatus of example 1, wherein the power plane and the impedance cushion are not directly coupled; and further comprising one or more electrical coupling directly coupled with the power plane and with the impedance cushion.

Example 11 may include the apparatus of any one of examples 1-10, wherein the impedance cushion and the power plane are unitary.

Example 12 is a package comprising: a power apparatus that includes: a power plane to provide voltage for the package; and an impedance cushion coupled with the power plane; and a dielectric layer directly coupled with a side of the power apparatus.

Example 13 may include the package of example 12, wherein the impedance cushion is at least partially within the dielectric layer.

Example 14 may include the package of example 12, further comprising a ground plane coupled with the dielectric layer opposite the power apparatus.

Example 15 may include the package of example 14, further comprising one or more signal traces disposed between the ground plane and the power apparatus, wherein the impedance cushion is dimensioned to change resonance characteristics of the power plane during operation to mitigate RFI or EMI affecting the one or more signal traces.

Example 16 may include the package of example 15, wherein a side of the impedance cushion and a side of the power plane form a plane.

Example 17 may include the package of example 12, wherein the impedance cushion is a first impedance cushion with a first thickness value; and further comprising a second impedance cushion with a second thickness value coupled with the power plane or with the first impedance cushion.

Example 18 may include the package of example 17, wherein the power plane has a first side and a second side opposite the first side; and wherein the first impedance cushion is directly coupled to the first side of the power plane and the second impedance cushion is directly coupled to the second side of the power plane.

Example 19 may include the package of any one of examples 12-18, wherein the power plane, first impedance cushion, and second impedance cushion are unitary.

Example 20 may include the package of example 12, wherein the power plane and the impedance cushion are not directly coupled; and further comprising one or more electrical coupling directly coupled with the power plane and with the impedance cushion.

Example 21 may be a method comprising: applying metallic foil to a first side and to a second side of a prepeg material, wherein the first side is opposite the second side; and applying a metal layer to the metallic foil of the first side of the prepeg material to form at least a portion of an impedance cushion.

Example 22 may be the method of example 21, wherein applying the metal layer further includes: applying a photoresist coating; applying a photo mask on the photoresist coating, wherein the photo mask is to identify a location of at least a portion of the impedance cushion; exposing at least a portion of the photoresist coating to a laser to cure the at least the portion of the photoresist; removing the photo mask and dissolving uncured photoresist; and applying electrolytic plating.

Example 23 may be the method of example 22, further comprising stripping the cured photoresist.

Example 24 may be the method of any one of examples 21-23, wherein the metal layer is a first metal layer; and further comprising applying a second metal layer to form at least a portion of the impedance cushion.

Example 25 may be the method of example 21, wherein the metallic foil is copper or the electrolytic plating is copper.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus, comprising:
a power plane to provide voltage for a system; and
an impedance cushion coupled with the power plane, wherein the impedance cushion is dimensioned to suppress resonance of the power plane during operation to mitigate radio frequency interference (RFI) or electromagnetic interference (EMI) emanating from the power plane.

2. The apparatus of claim 1, wherein the impedance cushion is directly coupled with the power plane; and wherein a side of the impedance cushion and a side of the power plane form a plane.

3. The apparatus of claim 1, wherein the impedance cushion and the power plane are made of metal materials.

4. The apparatus of claim 3, wherein the impedance cushion and the power plane are made of different metal materials or have different electrical conductivity properties.

5. The apparatus of claim 1, wherein the power plane has a first side and a second side opposite the first side;
wherein the impedance cushion is coupled to the second side of the power plane; and
wherein the second side of the power plane and the impedance cushion are to couple with a dielectric material.

6. The apparatus of claim 1, wherein the impedance cushion has a uniform thickness.

7. The apparatus of claim 1, wherein the impedance cushion is a first impedance cushion with a first thickness value; and further comprising a second impedance cushion with a second thickness value directly coupled with the power plane or with the first impedance cushion.

8. The apparatus of claim 7, wherein the first thickness value and the second thickness value are different values.

9. The apparatus of claim 7, wherein a side of the second impedance cushion and a side of the power plane form a plane.

10. The apparatus of claim 1, wherein the power plane and the impedance cushion are not directly coupled; and further comprising one or more electrical coupling directly coupled with the power plane and with the impedance cushion.

11. The apparatus of claim 1, wherein the impedance cushion and the power plane are unitary.

12. A package comprising:
a power apparatus that includes:
a power plane to provide voltage for the package; and
an impedance cushion coupled with the power plane; and
a dielectric layer directly coupled with a side of the power apparatus.

13. The package of claim 12, wherein the impedance cushion is at least partially within the dielectric layer.

14. The package of claim 12, further comprising a ground plane coupled with the dielectric layer opposite the power apparatus.

15. The package of claim 14, further comprising one or more signal traces disposed between the ground plane and the power apparatus, wherein the impedance cushion is dimensioned to change resonance characteristics of the power plane during operation to mitigate RFI or EMI affecting the one or more signal traces.

16. The package of claim 15, wherein a side of the impedance cushion and a side of the power plane form a plane.

17. The package of claim 12, wherein the impedance cushion is a first impedance cushion with a first thickness value; and further comprising a second impedance cushion with a second thickness value coupled with the power plane or with the first impedance cushion.

18. The package of claim 17, wherein the power plane has a first side and a second side opposite the first side; and wherein the first impedance cushion is directly coupled to the first side of the power plane and the second impedance cushion is directly coupled to the second side of the power plane.

19. The package claim 18, wherein the power plane, first impedance cushion, and second impedance cushion are unitary.

20. The package of claim 12, wherein the power plane and the impedance cushion are not directly coupled; and further comprising one or more electrical coupling directly coupled with the power plane and with the impedance cushion.

21. A method comprising:
applying metallic foil to a first side and to a second side of a prepeg material, wherein the first side is opposite the second side; and
applying a metal layer to the metallic foil of the first side of the prepeg material to form at least a portion of an impedance cushion.

22. The method of claim 21, wherein applying the metal layer further includes:
applying a photoresist coating;
applying a photo mask on the photoresist coating, wherein the photo mask is to identify a location of at least a portion of the impedance cushion;
exposing at least a portion of the photoresist coating to a laser to cure the at least the portion of the photoresist;
removing the photo mask and dissolving uncured photoresist; and
applying electrolytic plating.

23. The method of claim 22, further comprising stripping the cured photoresist.

24. The method of claim 21, wherein the metal layer is a first metal layer; and further comprising applying a second metal layer to form at least a portion of the impedance cushion.

25. The method of claim 21, wherein the metallic foil is copper or the electrolytic plating is copper.
